(19) United States
(12) Patent Application Publication
(10) Pub. No.: US 2016/0104746 A1
(43) Pub. Date: Apr. 14, 2016

(54) METHODS OF FABRICATING A VARIABLE RESISTANCE MEMORY DEVICE USING MASKING AND SELECTIVE REMOVAL

(71) Applicant: Samsung Electronics Co., Ltd., Gyeonggo-do (KR)

(72) Inventors: YOUNGSOO LIM, Cheongju-si (KR); SOONWON HWANG, Seoul (KR); KI-JIN PARK, Seoul (KR)

(21) Appl. No.: 14/801,030

(22) Filed: Jul. 16, 2015

(30) Foreign Application Priority Data
Oct. 10, 2014 (KR) 10-2014-0136839

(51) Int. Cl. H01L 27/24; H01L 21/308; H01L 21/768; H01L 21/02; H01L 21/311; H01L 21/3213; H01L 21/306; H01L 21/3105

(52) U.S. Cl. CPC H01L 27/2409; H01L 27/2436; H01L 21/30604; H01L 21/3081; H01L 21/31051; H01L 21/02164; H01L 21/0217; H01L 21/31111; H01L 21/32139; H01L 21/768

(57) ABSTRACT

A semiconductor device is fabricated by forming a semiconductor layer on a substrate, patterning the semiconductor layer in a first direction parallel to a top surface of the substrate to form semiconductor patterns extending parallel to the first direction, forming sacrificial patterns in gap regions between the semiconductor patterns, forming mask patterns on the semiconductor patterns and the sacrificial patterns extending parallel to a second direction crossing the first direction, removing the sacrificial patterns, and patterning the semiconductor patterns using the mask patterns as an etch mask to form an array of selection devices for a variable resistance memory device on the substrate.

### CROSS-REFERENCE TO RELATED APPLICATION

This U.S. non-provisional patent application claims priority under 35 U.S.C. §119 to Korean Patent Application No. 10-2014-0136839, filed on Oct. 10, 2014, in the Korean Intellectual Property Office, the entire contents of which are hereby incorporated by reference.

### BACKGROUND

Example embodiments of the inventive concepts relate to methods of fabricating a semiconductor device, and in particular, to methods of fabricating a variable resistance memory device.

Semiconductor devices include memory devices and logic devices. The memory devices for storing data include volatile memory devices and nonvolatile memory devices. The volatile memory devices may lose their stored data when their power supplies are interrupted. The volatile memory devices may, for instance, include a dynamic random access memory (DRAM) and a static random access memory (SRAM). The nonvolatile memory devices may maintain their stored data even when their power supplies are interrupted and may, for instance, include a programmable read only memory (PROM), an erasable PROM (EPROM), an electrically EPROM (EEPROM) and a flash memory device.

Also, to meet the demand for semiconductor memory devices with high performance and low power consumption, other semiconductor memory devices have been developed. For example, a ferroelectric random access memory (FRAM), a magnetic random access memory (MRAM), and a phase change random access memory (PRAM) have been developed as candidates for high performance, low power consumption semiconductor memory devices. In these semiconductor memory devices, a material or structure, whose resistance can be changed by a current or voltage applied thereto and can be maintained even when a current or voltage supply is interrupted, is used as a memory element. Thus, these memory devices may be referred to generically as variable resistance memory devices.

### SUMMARY

Example embodiments of the inventive concepts provide methods that can prevent a short circuit from being formed between selection devices of a variable resistance memory device and thereby can provide a variable resistance memory device with improved reliability.

According to example embodiments of the inventive concepts, a method of fabricating a semiconductor device may include forming a semiconductor layer on a substrate, patterning the semiconductor layer in a first direction parallel to a top surface of the substrate to form semiconductor patterns extending parallel to the first direction, forming sacrificial patterns in, and in some embodiments to fill, gap regions between the semiconductor patterns, forming mask patterns on the semiconductor patterns and the sacrificial patterns extending parallel to a second direction crossing the first direction, removing the sacrificial patterns, and patterning the semiconductor patterns using the mask patterns as an etch mask to form an array of selection devices for a variable resistance memory device on the substrate.

In example embodiments, the forming sacrificial patterns may include forming a sacrificial layer on, and in some embodiments to cover, the semiconductor patterns and planarizing the sacrificial layer to form the sacrificial patterns. The removing the sacrificial patterns may be performed so that the semiconductor patterns and the mask patterns remain and the sacrificial patterns are removed.

In example embodiments, the sacrificial patterns may include a spin on hardmask (SOH) layer, a silicon oxide layer and/or a silicon nitride layer. The sacrificial patterns may be removed by an ashing process and/or an etching process, in which hydrogen fluoride and/or phosphoric acid may be used.

In example embodiments, the removing the sacrificial patterns may form empty spaces below the mask patterns.

In example embodiments, the empty spaces may be spaced apart from each other by the semiconductor patterns interposed therebetween and may be formed to extend parallel to the first direction, and the mask patterns may span the empty spaces.

In example embodiments, the removing of the sacrificial patterns may be performed to expose top and side surfaces of the semiconductor patterns between the mask patterns.

In example embodiments, when viewed in a plan view, each of the semiconductor patterns may include first regions overlapped with the mask patterns and second regions exposed by the mask patterns. The patterning the semiconductor patterns may include removing, and in some embodiments completely removing, the second regions so that the first regions remain to form the array of selection devices.

In example embodiments, the removing the second regions may completely separate the first regions from each other in the first direction.

In example embodiments, the removing of the sacrificial patterns may be performed to expose top and side surfaces of the second regions.

In example embodiments, the semiconductor patterns have a width that decreases in a direction away from the substrate.

In example embodiments, the semiconductor patterns may be separated from each other in the second direction.

In example embodiments, the forming a semiconductor layer on the substrate may be preceded by forming a conduction region on the substrate. The patterning of the semiconductor layer in the first direction may also pattern the conduction region into a plurality of conductive lines.

In example embodiments, the forming the semiconductor layer comprises forming a first semiconductor layer, which is doped to have a first conductivity type and forming a second semiconductor layer, which is doped to have a second conductivity type different from the first conductivity type, on the first semiconductor layer. Each of the selection devices is a diode having lower and upper portions with different conductivity types from each other, i.e., having a p-n junction that extends along the first and second directions.

In example embodiments, the method may further include forming lower electrode patterns on the selection devices and forming memory elements on the lower electrode patterns connected to the selection devices.

In example embodiments, the memory elements may include a phase-changeable material.

According to example embodiments of the inventive concepts, a method of fabricating a semiconductor device may include forming a semiconductor layer on a substrate, patterning the semiconductor layer in a first direction parallel to a top surface of the substrate to form semiconductor patterns spaced apart from each other in a second direction crossing the first direction, forming empty spaces between the semiconductor patterns, and patterning the semiconductor patterns in the second direction, to form an array of selection devices for a variable resistance memory device on the substrate.

In example embodiments, the semiconductor patterns may be formed to have sidewalls that have a positive slope.

In example embodiments, the patterning the semiconductor patterns in the second direction may include forming mask patterns overlying the semiconductor patterns and the empty spaces in the second direction and etching top and side surfaces of the semiconductor patterns exposed by the mask pattern to form the selection devices between the etched portions of the semiconductor patterns. The selection devices may be separated from each other in the first direction.

In example embodiments, the method may further include forming a sacrificial layer in, and in some embodiments to fill, gap regions between the semiconductor patterns, and the forming mask patterns may include forming the mask patterns to cross the semiconductor patterns and extend in the second direction and removing the sacrificial layer below the mask patterns to form the empty spaces so that the mask patterns overlie the semiconductor patterns and the empty spaces in the second direction. The patterning the semiconductor patterns may be performed to form first portions of the semiconductor patterns below the mask patterns and remove second portions of the semiconductor patterns exposed by the mask patterns.

In example embodiments, the forming of the semiconductor layer comprises forming a first semiconductor layer, which is doped to have a first conductivity type, and forming a second semiconductor layer, which is doped to have a second conductivity type different from the first conductivity type, on the first semiconductor layer.

According to other example embodiments of the inventive concepts, a method of fabricating a semiconductor device may comprise forming on a substrate, a plurality of interleaved semiconductor lines and insulator lines that extend along the substrate in a first direction, forming on the interleaved semiconductor lines and insulator lines, a plurality of mask lines that extend along the substrate in a second direction that crosses the first direction, removing at least portions of the insulator lines that lie beneath the plurality of mask lines, and then patterning the plurality of semiconductor lines in the second direction using the plurality of mask lines.

In example embodiments, the removing comprises removing sufficient portions of the insulator lines beneath the plurality of mask lines to form an empty space beneath a respective mask line that extends across the respective mask line in the first direction.

In other example embodiments, the removing comprises completely removing the portions of the insulator lines that lie beneath the plurality of mask lines so that the plurality of mask lines span across the substrate between adjacent ones of the semiconductor lines.

In still other example embodiments, the removing comprises completely removing the insulator lines.

In example embodiments, a respective semiconductor line comprises a p-n junction therein and the patterning forms an array of spaced apart p-n junctions on the substrate that extends along the first and second directions.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram illustrating a memory cell array of a variable resistance memory device according to example embodiments of the inventive concepts.

FIGS. 2A through 8A and 10A are schematic plan views illustrating a method of fabricating a variable resistance memory device, according to example embodiments of the inventive concepts.

FIGS. 2B through 8B, 9 and 10B are sectional views, each of which illustrates sections taken along lines A-A′, B-B′, and C-C′ of FIGS. 2A through 8A and 10A and which are provided to illustrate a method of fabricating a variable resistance memory device, according to example embodiments of the inventive concepts.

FIG. 10A also is a schematic plan view illustrating a variable resistance memory device according to example embodiments of the inventive concepts.

FIG. 10B also is a sectional view illustrating sections taken along lines A-A′, B-B′, and C-C′ of FIG. 10A.

FIG. 11 is a schematic plan view illustrating a method of fabricating a variable resistance memory device according to a comparative example.

FIGS. 12 and 13 are sectional views, each of which illustrates sections taken along lines A-A′, B-B′, and C-C′ of FIG. 11, and which are provided to illustrate a method of fabricating a variable resistance memory device according to a comparative example.

FIG. 14 is a block diagram illustrating an example of an electronic device including a variable resistance memory device according to example embodiments of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “on”, “connected” or “coupled” to another element, it can be directly on, connected or coupled to the other element or intervening elements may be present. In contrast, when an element is referred to as being “directly on”, “directly connected” or “directly coupled” to another element, there are no intervening elements present. Like numbers indicate like elements throughout. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, steps, operations, elements and/or components, but do not preclude the presence or addition of one or more other features, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

In some embodiments of the present inventive concepts, a three dimensional (3D) memory array is provided. The 3D memory array is monolithically formed in one or more physical levels of arrays of memory cells having an active area disposed above a substrate and circuitry associated with the operation of those memory cells, whether such associated circuitry is above or within such substrate. The term “monolithic” means that layers of each level of the array are directly deposited on the layers of each underlying level of the array.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

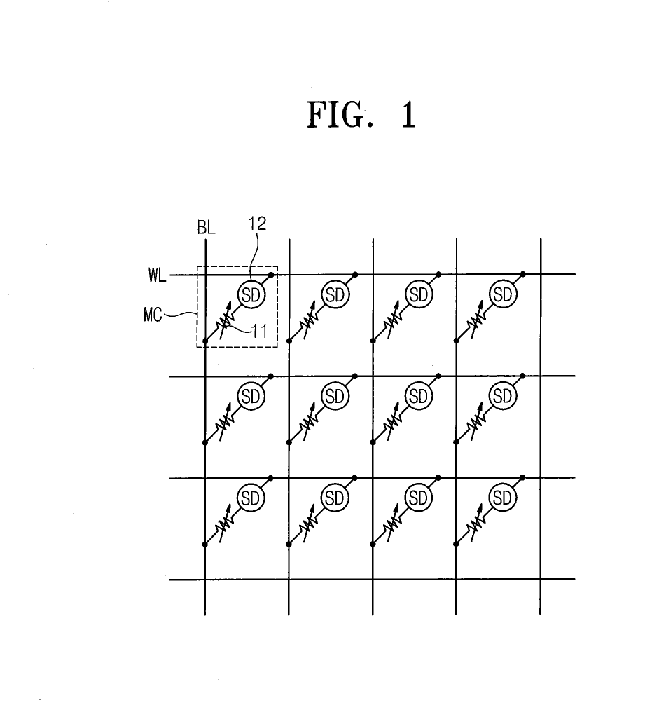

FIG. 1 is a circuit diagram illustrating a memory cell array of a variable resistance memory device according to example embodiments of the inventive concepts.

Referring to FIG. 1, a plurality of memory cells MC may be arranged in a matrix shape, in a memory cell array. Each of the memory cells MC may include a variable resistance device 11 and a selection device (SD) 12. The variable resistance device 11 and the selection device 12 may be interposed between a bit line BL and a word line WL.

The variable resistance device 11 may be configured in such a way that electric resistance thereof is changed by an amount of current to be supplied through the bit line BL. The selection device 12 may be provided to connect the variable resistance device 11 to the word line WL, and depending on a voltage of the word line WL, an amount of current to be supplied to the variable resistance device 11 may be controlled by the selection device 12. The selection device 12 may be a diode, a metal-oxide-semiconductor (MOS) transistor and/or a bipolar transistor, and may be regarded as a switch.

Hereinafter, example embodiments of the inventive concepts will be described with reference to a phase-changeable memory device, in which a phase-changeable material is used as the variable resistance device 11 of each memory cell, but example embodiments of the inventive concepts may not be limited thereto. By adjusting temperature and quenching time of the phase-changeable material, the phase-changeable material can have one of an amorphous structure (or a high resistance state) or a crystalline structure (or a low resistance state). In general, the amorphous structure may be called a set state and the crystalline structure may be called a reset state. In the phase-changeable memory device, the phase-changeable material may be heated using an amount of current supplied through a lower electrode and the consequent Joule heat.

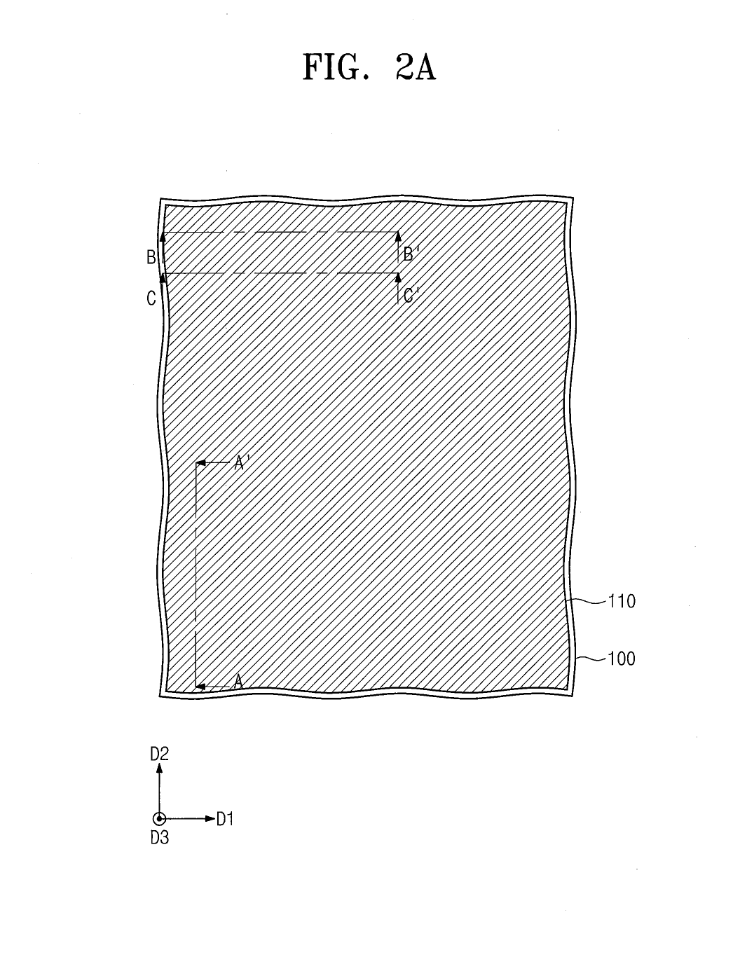

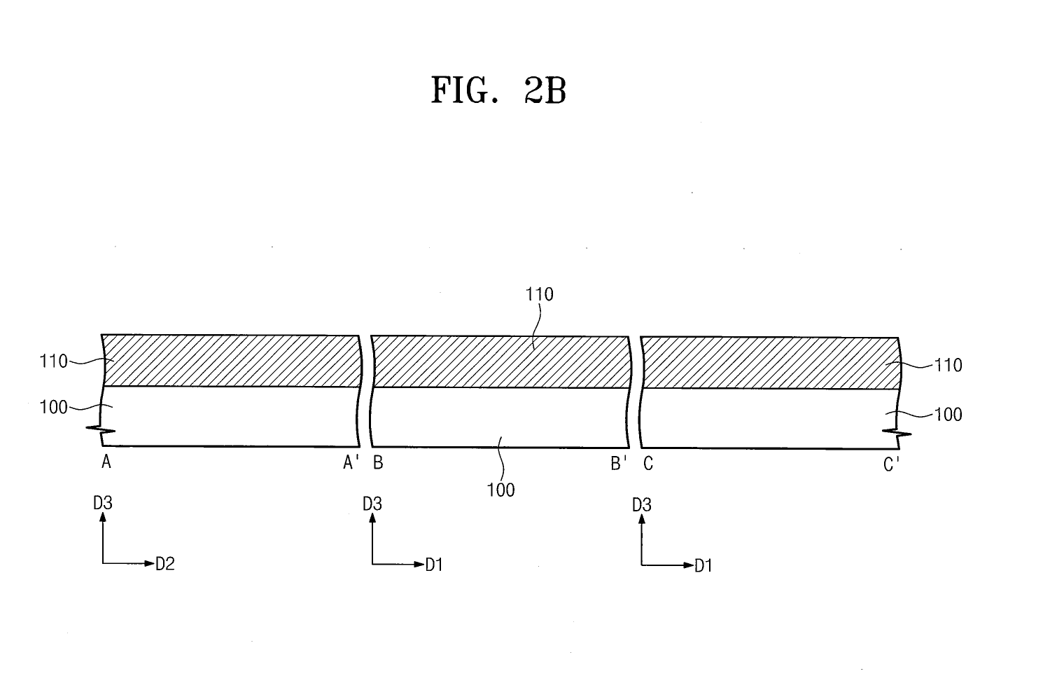

FIGS. 2A through 8A and 10A are schematic plan views illustrating a method of fabricating a variable resistance memory device, according to example embodiments of the inventive concepts. FIGS. 2B through 8B, 9, and 10B are sectional views, each of which illustrates sections taken along lines A-A′, B-B′, and C-C′ of FIGS. 2A through 8A and 10A, and which are provided to illustrate a method of fabricating a variable resistance memory device, according to example embodiments of the inventive concepts.

Referring to FIGS. 2A and 2B, a substrate 100 may be provided. The substrate 100 may be a semiconductor substrate (e.g., comprising silicon, silicon germanium (SiGe), germanium (Ge), and/or gallium arsenic (GaAs)) and/or a semiconductor-on-silicon wafer such as a silicon-on-insulator (SOI) wafer. The substrate 100 may be doped to have a first conductivity type. For example, the substrate 100 may be a lightly-doped p-type silicon wafer.

A conduction region 110 may be formed on the substrate 100. The conduction region 110 may be a metal layer. The metal layer may include one of transition metals, conductive transition metal nitrides and/or conductive ternary nitrides. As an example, the conduction region 110 may be a tungsten layer deposited on the substrate 100.

Alternatively, the conduction region 110 may be an impurity region that is formed to have a second conductivity type (e.g., n-type) different from that of the substrate 100. As an example, the conduction region 110 may be formed by highly doping an upper portion of the substrate 100 with impurities. After the formation of the conduction region 110, a thermal treatment process may be performed to cure crystal defects created by the doping process.

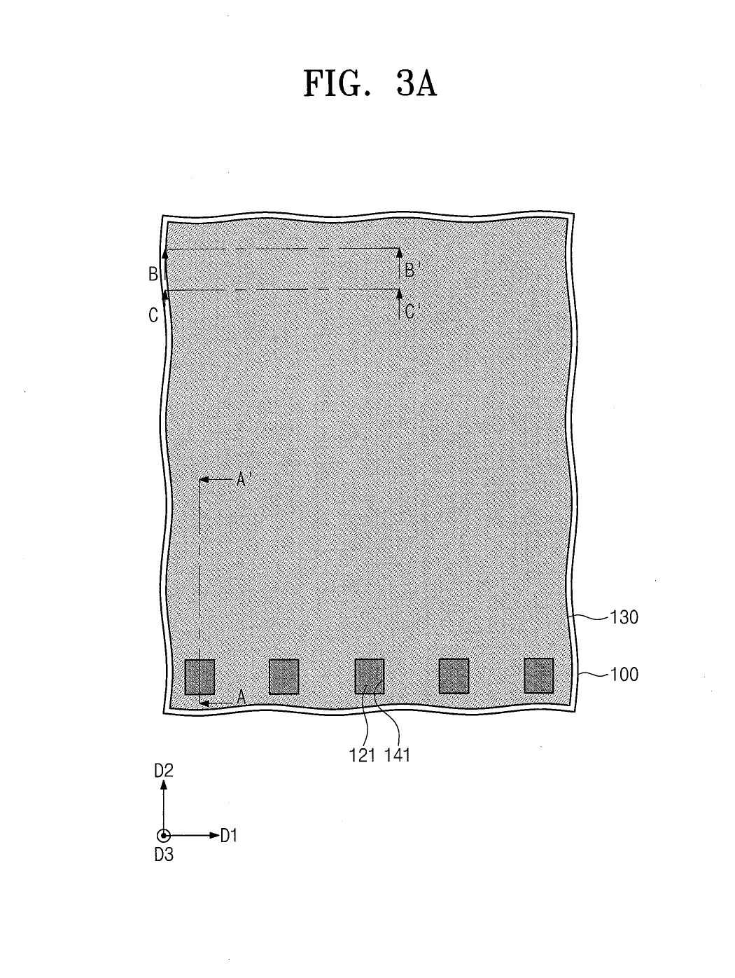

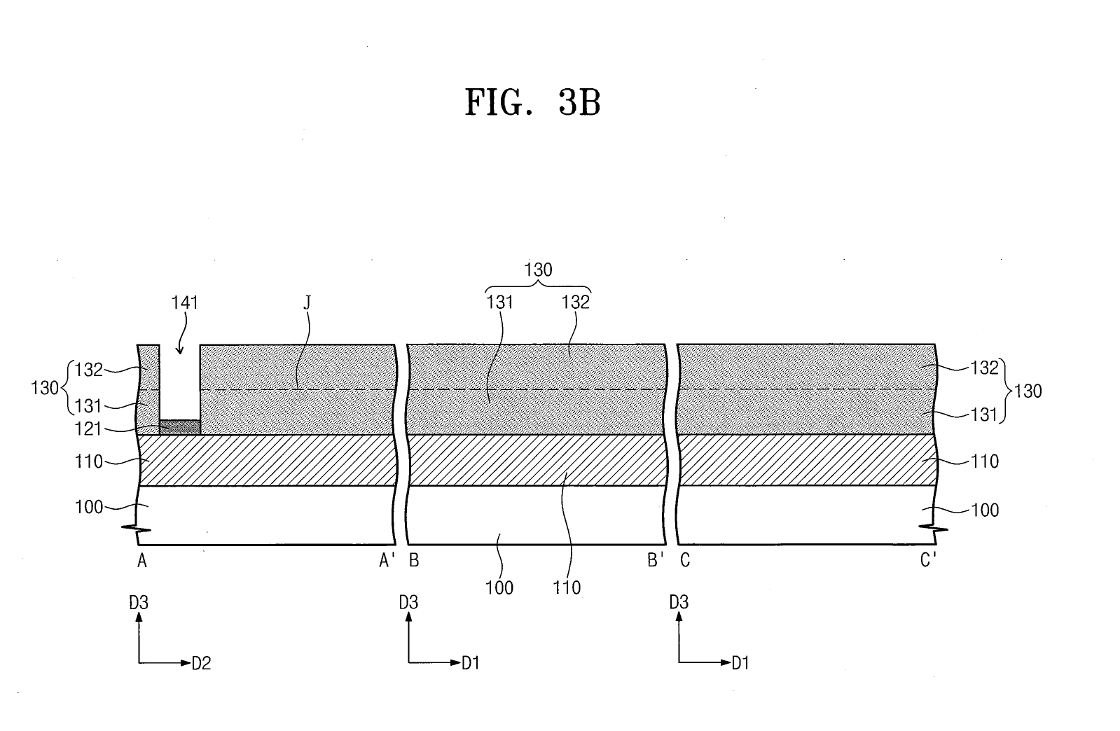

Referring to FIGS. 3A and 3B, an etch stop layer 121 may be formed on the conduction region 110. The etch stop layer 121 may be formed at positions of contact holes, which will be formed in a subsequent process. The etch stop layer 121 may be formed by deposition and patterning processes. The etch stop layer 121 may be formed of a material different from that of the substrate 100. As an example, the etch stop layer 121 may include a silicon nitride layer and/or a silicon oxynitride layer.

A semiconductor layer 130 may be formed on the substrate 100. The semiconductor layer 130 may include a semiconductor element such as silicon, silicon-germanium (SiGe), and/or germanium (Ge). The semiconductor layer 130 may be formed by, for example, a metal organic chemical vapor deposition (MOCVD), molecular beam epitaxy (MBE), liquid phase epitaxy (LPE) and/or vapor phase epitaxy (VPE) process. The semiconductor layer 130 may include a lower impurity region 131, which has the second conductivity type and an upper impurity region 132, which is provided on the lower impurity region 131 and has the first conductivity type. As an example, the lower impurity region 131 may be an n-type impurity region, and the upper impurity region 132 may be a p-type impurity region. The lower impurity region 131 and the upper impurity region 132 may be formed by an ion implantation process or an in-situ doping process. Thus, the semiconductor region 130 may have a p-n junction J therein, as indicated by the dashed horizontal line in FIG. 3B.

The semiconductor layer 130 may be formed on the conduction region 110, except for the etch stop layer 121. The semiconductor layer 130 may be deposited or grown to define a first opening 141 on the etch stop layer 121. In other example embodiments, an insulating layer (not shown) may be formed on the etch stop layer 121, and in this case, the first opening 141 may not be formed.

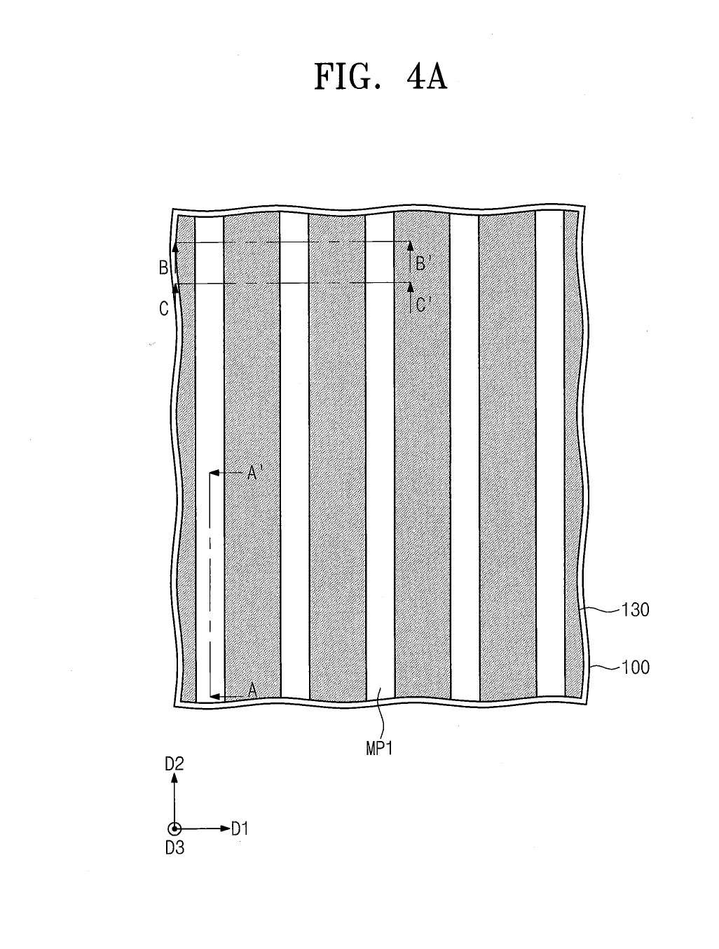

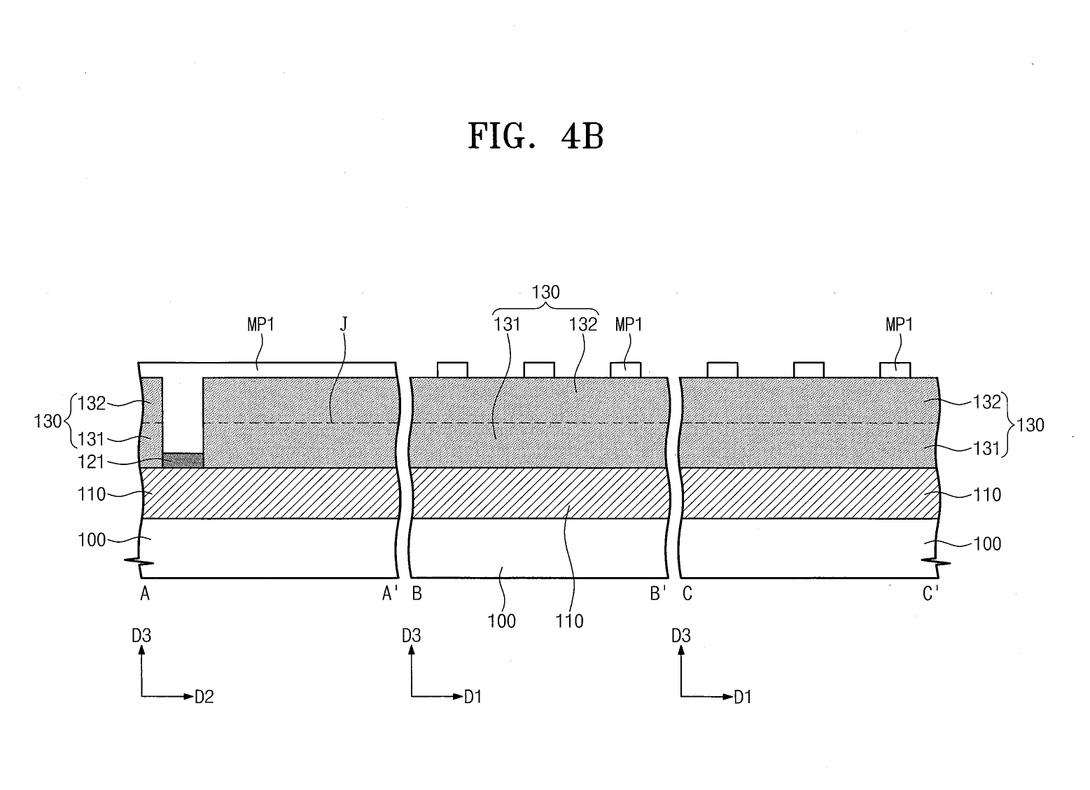

Referring to FIGS. 4A and 4B, first mask patterns MP1 may be formed on the semiconductor layer 130. Each of the first mask patterns MP1 may be a line-shaped structure extending along a second direction D2 parallel to the top surface of the substrate 100, i.e. extending along the substrate. The first mask patterns MP1 may be spaced apart from each other in a first direction D1 crossing the second direction D2. The formation of the first mask patterns MP1 may include forming a first mask layer (not shown) on the semiconductor layer 130 and performing a patterning process to separate the first mask layer into the first mask patterns MP1 parallel to the second direction D2. Here, the first mask layer may be formed to fill the first opening 141. The first mask patterns MP1 may be formed in the first opening 141 and may be overlapped with the etch stop layer 121, when viewed in a plan view. The first mask patterns MP1 may be formed of or include, for example, a silicon nitride layer and/or a silicon oxynitride layer.

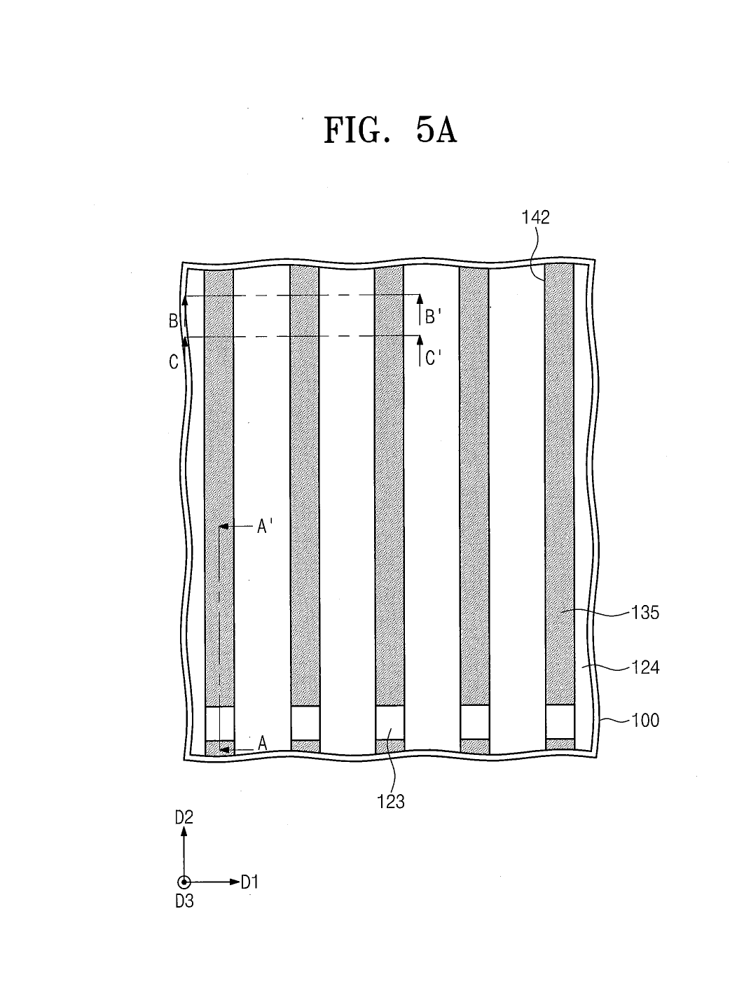

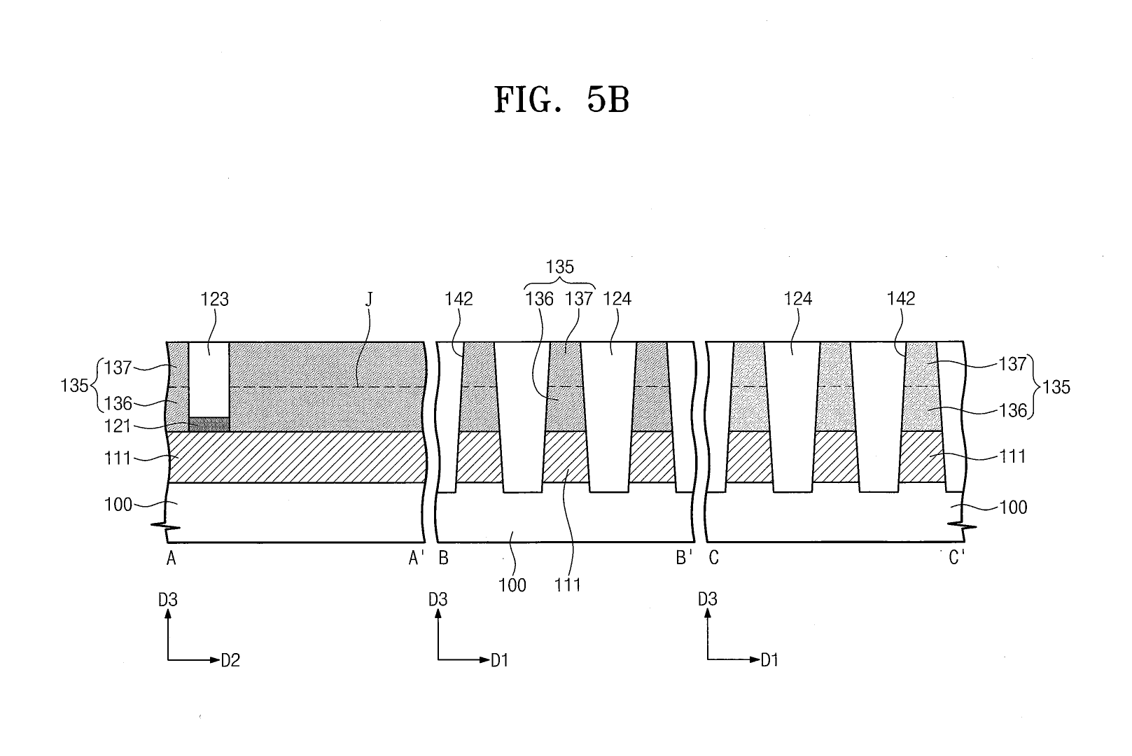

Referring to FIGS. 5A and 5B, the semiconductor layer 130 may be patterned using the first mask patterns MP1 as an etch mask to form semiconductor patterns 135, also referred to as semiconductor lines 135. In other words, as a result of the patterning of the semiconductor layer 130, each of the semiconductor patterns 135 may be formed to have a line or strip shape extending parallel to the second direction D2. The semiconductor patterns 135 may be spaced apart from each other in the first direction D1. Each of the semiconductor patterns 135 may include a lower impurity pattern 136 and an upper impurity pattern 137. The semiconductor patterns 135 may be defined by first trenches 142, which are formed by the patterning of the semiconductor layer 130. After the formation of the semiconductor patterns 135, the first mask patterns MP1 may be removed.

The patterning of the semiconductor layer 130 may be further performed to divide the conduction region 110 into a plurality of first conductive lines 111. The first conductive lines 111 may be formed along the semiconductor patterns 135 or parallel to the second direction D2 and may be spaced apart from each other in the first direction D1. In example embodiments, the first conductive lines 111 may serve as word lines in the variable resistance memory device.

The patterning of the semiconductor layer 130 and the conduction region 110 may be performed using a dry etching process. In example embodiments, sidewalls of the semiconductor patterns 135 may be formed to have a positive slope. For example, each of the semiconductor patterns 135 may be formed to have a gradually decreasing width in a direction away from the top surface of the substrate 100.

Thereafter, sacrificial patterns 124, also referred to as insulator lines 124, may be formed in, and in some embodiments to fill, gap regions (e.g., the first trenches 142) between the semiconductor patterns 135. The sacrificial patterns 124 may extend parallel to the second direction D2 and may be spaced apart from each other in the first direction D1 with the semiconductor patterns 135 interposed therebetween. For example, the formation of the sacrificial patterns 124 may include forming a sacrificial layer (not shown) in, and in some embodiments to fill, the first trenches 142 and cover the semiconductor patterns 135, and then, planarizing the sacrificial layer to expose top surfaces of the semiconductor patterns 135. In example embodiments, the sacrificial patterns 124 may be formed using a shallow trench isolation (STI) process. Accordingly, FIGS. 2A-5B illustrate forming on a substrate 100 a plurality of interleaved semiconductor lines 135 and insulator lines 124 that extend along the substrate 100 in the second direction D2.

The sacrificial patterns 124 may include a material capable of supporting second mask patterns MP2, which will be formed thereon in a subsequent process. Further, the material for the sacrificial patterns 124 may be chosen to be selectively removed without significant damage of the semiconductor patterns 135, the conductive lines 111, the substrate 100, and the second mask patterns MP2 described later. For example, the sacrificial patterns 124 may include a spin on hardmask (SOH) layer, a silicon oxide layer and/or a silicon nitride layer.

A first gap-filling layer 123 may be formed to fill the first opening 141. In certain embodiments, the first gap-filling layer 123 may be a remaining portion of the first mask pattern MP1 that is not removed from the first opening 141. Alternatively, the first gap-filling layer 123 may be a silicon oxide layer, which is formed using a high-density plasma chemical vapor deposition technology with a good gap-fill property.

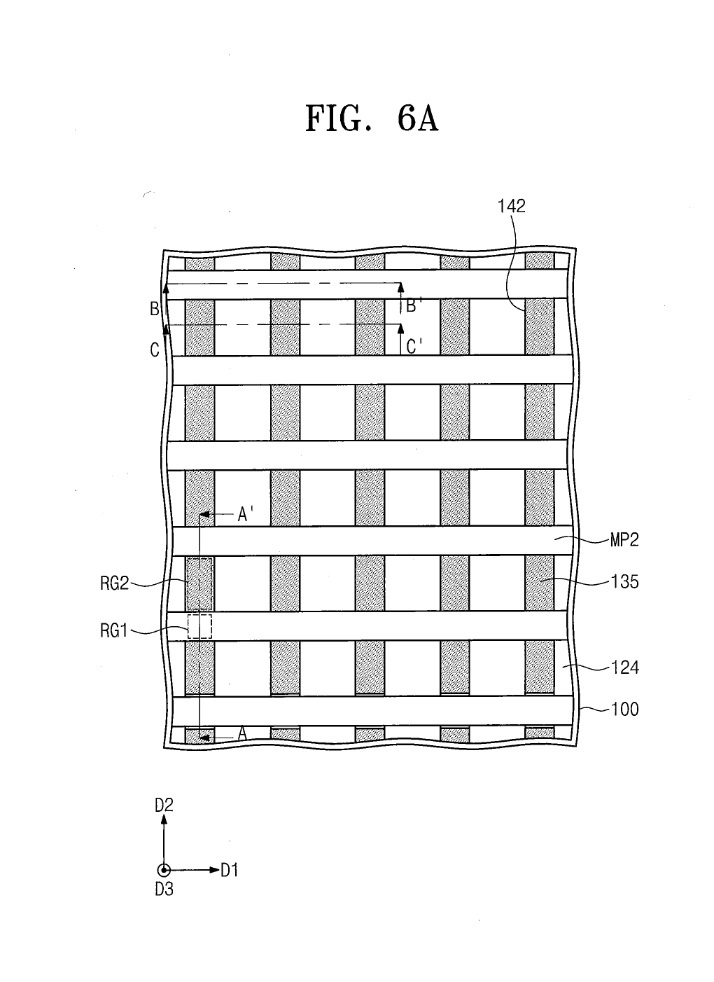

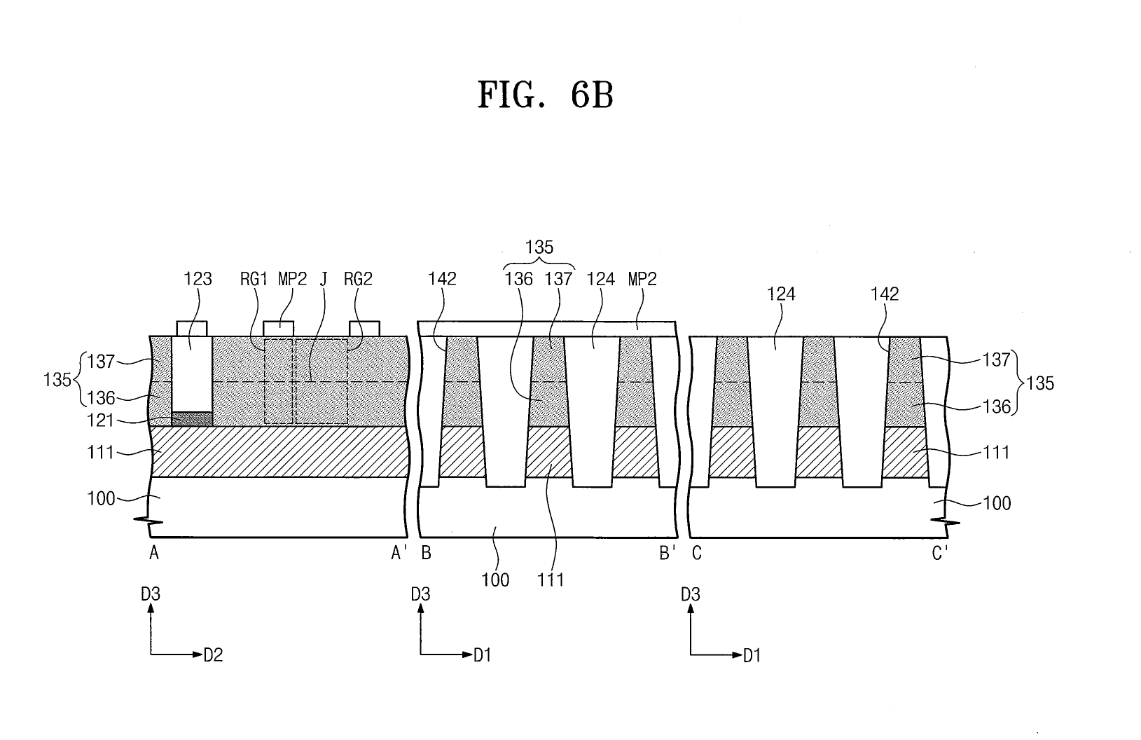

Referring to FIGS. 6A and 6B, second mask patterns MP2 may be formed on the semiconductor patterns 135 and the sacrificial patterns 124. Each of the second mask patterns MP2 may be a line-shape pattern crossing the semiconductor patterns 135 and the sacrificial patterns 124 and extending in the first direction D1. The second mask patterns MP2 may be spaced apart from each other in the second direction D2. The formation of the second mask patterns MP2 may include forming a second mask layer (not shown) on the semiconductor patterns 135 and the sacrificial patterns 124, and then, performing a patterning process to separate the second mask layer into the second mask patterns MP2 extending parallel to the first direction D1. At least one of the second mask patterns MP2 may be formed on the gap-filling layer 123 and may be overlapped with the etch stop layer 121, when viewed in a plan view. For example, the second mask patterns MP2 may include a silicon nitride layer or a silicon oxynitride layer. Thus, FIGS. 6A and 6B may be regarded as illustrating forming on the interleaved semiconductor lines 135 and insulator lines 124, a plurality of mask lines MP2 that extend along the substrate in the first direction D1 that crosses the second direction D2.

Each of the semiconductor patterns 135 may include a first region RG1 that is overlapped with a corresponding one of the second mask patterns MP2, when viewed in a plan view. Each of the semiconductor patterns 135 may include a second region RG2 that is adjacent to the first region RG1 and is exposed by a corresponding one of the second mask patterns MP2.

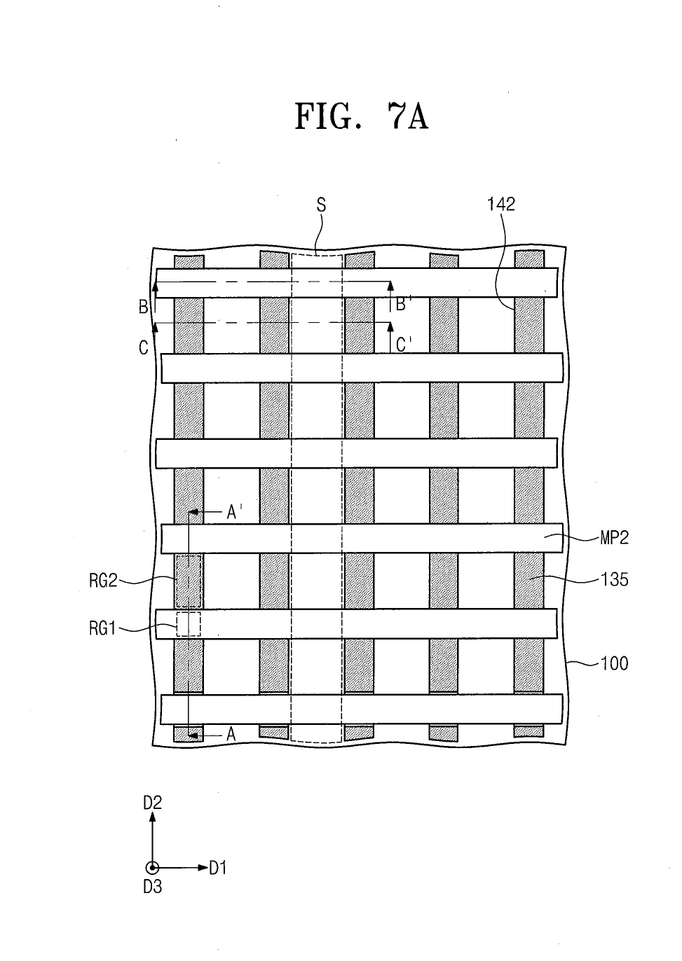

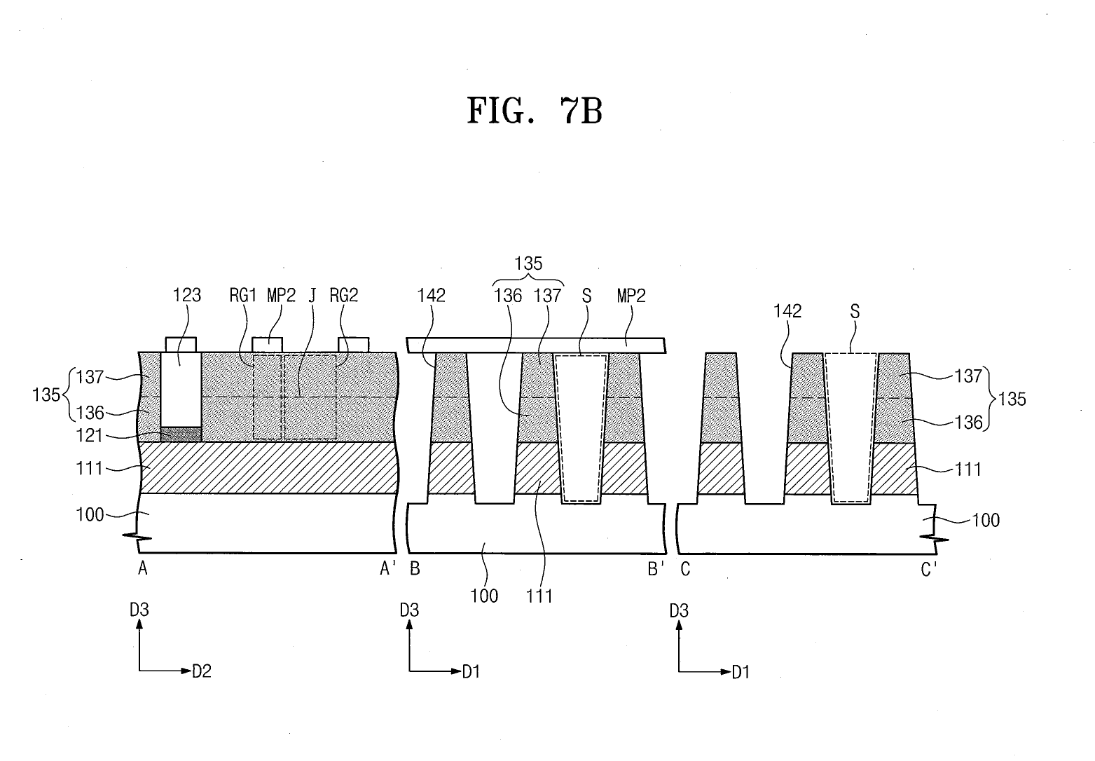

Referring to FIGS. 7A and 7B, the sacrificial patterns 124 may be selectively removed. For example, the sacrificial patterns 124 may be removed using a process capable of preventing the semiconductor patterns 135, the conductive lines 111, the substrate 100, and the second mask patterns MP2 from being significantly etched or removed. For example, in the case where the sacrificial patterns 124 include a spin-on-hardmask (SOH) layer, an aching process may be performed to selectively remove the sacrificial patterns 124. As another example, in the case where the sacrificial patterns 124 include a silicon oxide layer, the sacrificial patterns 124 may be selectively removed by a cleaning and/or etching process using a LAL solution containing hydrogen fluoride (HF). As still other example, in the case where the sacrificial patterns 124 include a silicon oxide layer, the sacrificial patterns 124 may be selectively removed by an etching process using hydrogen fluoride (HF) gas. As even other example, in the case where the sacrificial patterns 124 include a silicon nitride layer, the sacrificial patterns 124 may be selectively removed by a cleaning and/or etching process using phosphoric acid (H₃PO₄) solution.

The sacrificial patterns 124 may be removed to expose at least a portion of top and side surfaces of the semiconductor patterns 135 positioned between the second mask patterns MP2. In detail, at least a portion of top and side surfaces of the second region RG2 may be exposed.

The sacrificial patterns 124 may be removed to form empty spaces S below the second mask patterns MP2. The empty spaces S may be formed at the same positions as the first trenches 142. The empty spaces S may be spaced apart from each other with the semiconductor patterns 135 interposed therebetween and may extend parallel to the second direction D2. The second mask patterns MP2 may be formed to span the empty spaces S and extend parallel to the first direction D1. For example, as shown in a section taken along B-B′ of FIG. 7B, the second mask patterns MP2 may be a bridge connecting the semiconductor patterns 135 to each other.

FIGS. 7A and 7B may also be regarded as illustrating removing at least portions of the insulator lines 124 that lie beneath the plurality of mask lines MP2. As also illustrated, in some embodiments, the removing comprises removing sufficient portions of the insulator lines 124 beneath the plurality of mask lines MP2 to form an empty space S beneath a respective mask line MP2 that extends across the respective mask line MP2 in the second direction D2. These figures also illustrate other embodiments wherein the removing comprises completely removing the portions of the insulator lines 124 that lie beneath the plurality of mask lines MP2, so that the plurality of mask lines MP2 span across the substrate 100 between adjacent ones of the semiconductor lines 124. FIGS. 7A and 7B also illustrate other embodiments wherein the removing comprises completely removing the insulator lines 124.

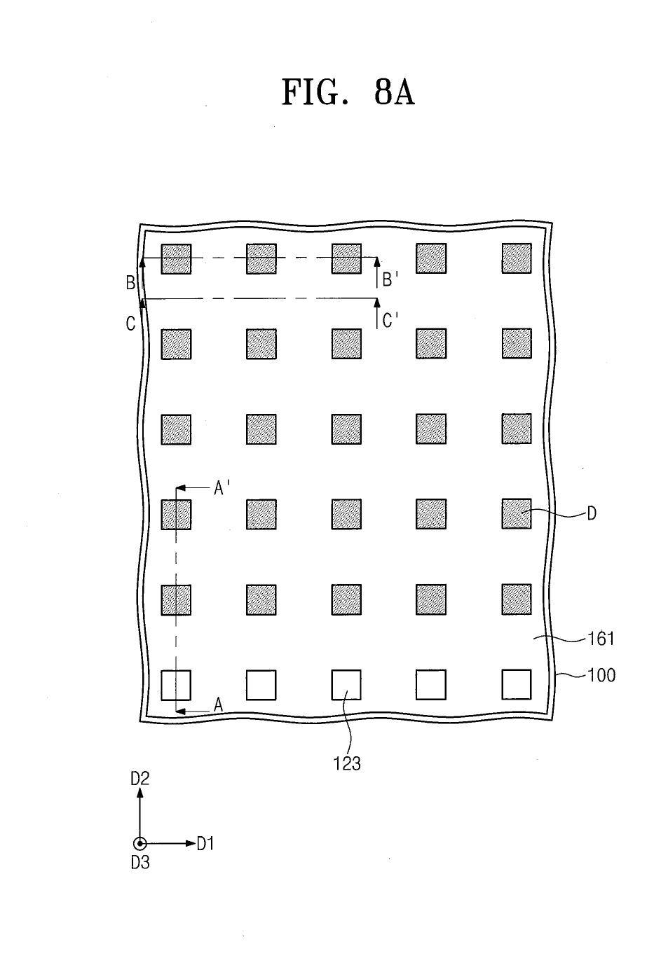

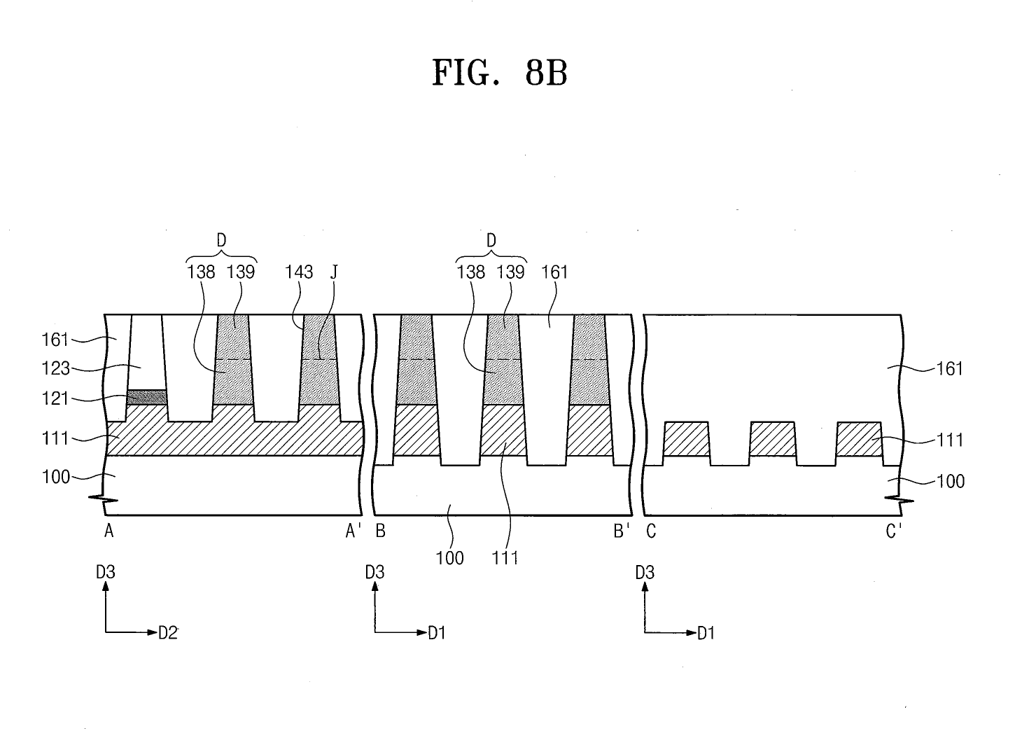

Referring to FIGS. 8A and 8B, the semiconductor patterns 135 may be patterned using the second mask patterns MP2 as an etch mask to form diodes D. For example, the semiconductor patterns 135 may be cut parallel to the first direction D1 to form the diodes D that are two-dimensionally arranged on the substrate 100. The diodes D may form a plurality of columns arranged in the first direction D1 and a plurality of rows arranged in the second direction D2. Each of the diodes D may include a lower impurity pillar 138 and an upper impurity pillar 139, which are formed by cutting the lower and upper impurity patterns 136 and 137 respectively. The diodes D may be formed on the conductive lines 111 (e.g., word lines) to serve as selection devices.

Stated differently, FIGS. 8A and 8B illustrate patterning the plurality of semiconductor lines 135 in the first direction D1 using the plurality of mask lines MP2. A respective semiconductor line 135 comprises a p-n junction J therein, so that the patterning forms an array of spaced p-n junctions on the substrate that extends along the first and second directions D1 and D2, respectively.

The process of patterning the semiconductor patterns 135 in the first direction D1 may be performed using a dry etching process. The process of patterning the semiconductor patterns 135 in the first direction D1 may be performed to expose portions of top surfaces of the first conductive lines 111. In example embodiments, sidewalls of the diodes D may be formed to have a positive slope. For example, each of the diodes D may be formed to have a gradually decreasing width in a direction away from the top surface of the substrate 100.

As a result of the formation of the diodes D, second trenches 143 may be formed. When the second trenches 143 are formed, top portions of the first conductive lines 111 may be partially recessed. For example, the first conductive lines 111 may not be divided in the second direction D2 by the patterning process performed in the first direction D1. Furthermore, although not shown, a top surface of the substrate 100 exposed by the empty spaces S may be partially etched, when the second trenches 143 are formed.

In other words, the second region RG2 may be wholly or completely exposed when the sacrificial patterns 124 are removed. In the case where the semiconductor patterns 135 are etched using the second mask patterns MP2 as an etch mask, the second region RG2 may be completely removed. Here, remaining portions of the first regions RG1 may be completely separated from each other to form the diodes D.

Further, the first gap-filling layer 123 and the etch stop layer 121 may also be patterned using the second mask patterns MP2 as an etch mask. In certain embodiments, sidewalls of the patterned first gap-filling layer 123 may be formed to have a positive slope, similar to those of the diodes D.

A first insulating layer 161 may be formed in, and in some embodiments to fill, gap regions between the diodes D. The formation of the first insulating layer 161 may include depositing a silicon nitride layer a silicon oxide layer, and/or a silicon oxynitride layer on the substrate 100 and planarizing it to expose top surfaces of the diodes D.

A method of fabricating a variable resistance memory device may be performed to remove the sacrificial patterns 124, before the patterning process

performed in the first direction D1, and thereby form the empty spaces S between the semiconductor patterns 135. Accordingly, portions of the semiconductor patterns 135 exposed by the second mask patterns MP2 may be completely removed by the patterning process performed in the first direction D1. Accordingly, it is possible to completely separate the diodes D from each other (i.e., to reduce or prevent a short circuit between the diodes D). If the patterning process of the semiconductor pattern 135 is performed in the first direction D1 without a step of removing the sacrificial patterns (i.e., insulator lines) 124, a short circuit may be formed between the diodes D, as will be described below with reference to a comparative example.

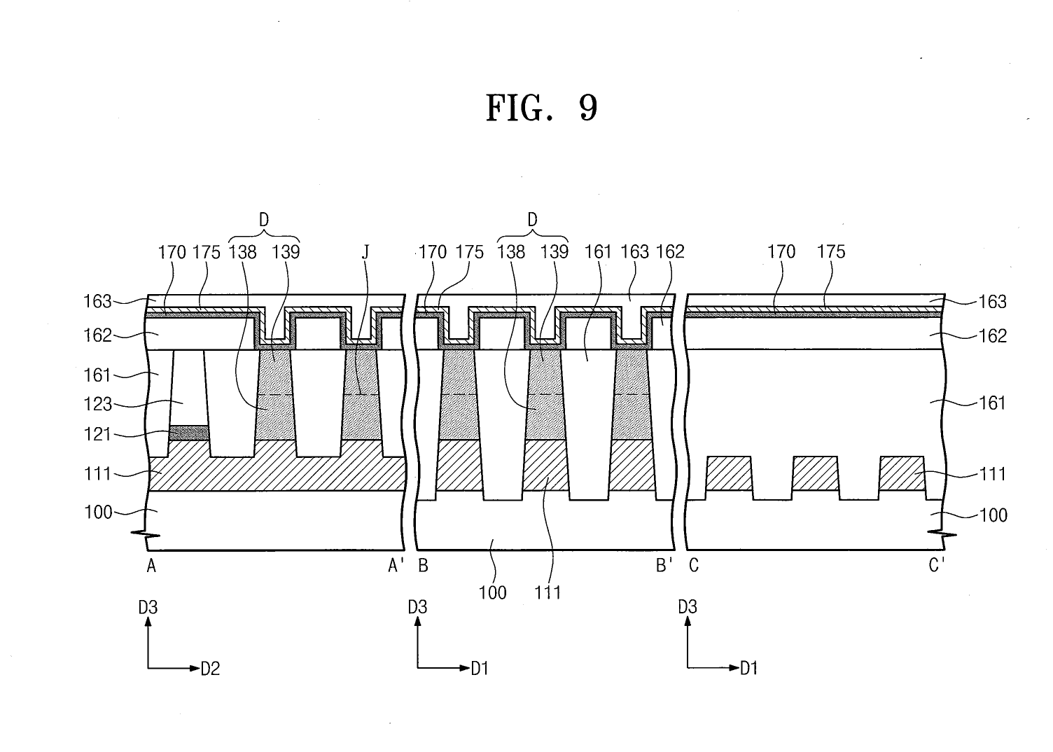

Referring to FIGS. 8A and 9, a first interlayer insulating layer 162 may be formed to expose the diodes D. A metal silicide layer 170, a lower electrode layer 175, and a second insulating layer 163 may be sequentially formed on the diodes D exposed by the first interlayer insulating layer 162. The lower electrode layer 175 may be formed of transition metals, conductive transition metal nitrides and/or conductive ternary nitrides. The second insulating layer 163 may be a silicon nitride layer, a silicon oxide layer, and/or a silicon oxynitride layer. The lower electrode layer 175 and the second insulating layer 163 may be formed by a sputtering and/or chemical vapor deposition (CVD) process. The metal silicide layer 170 may contribute to reduce a contact resistance between the diodes D and the lower electrode layer 175. The metal silicide layer 170 may be formed of metal silicides (e.g., cobalt silicide, nickel silicide and/or titanium silicide).

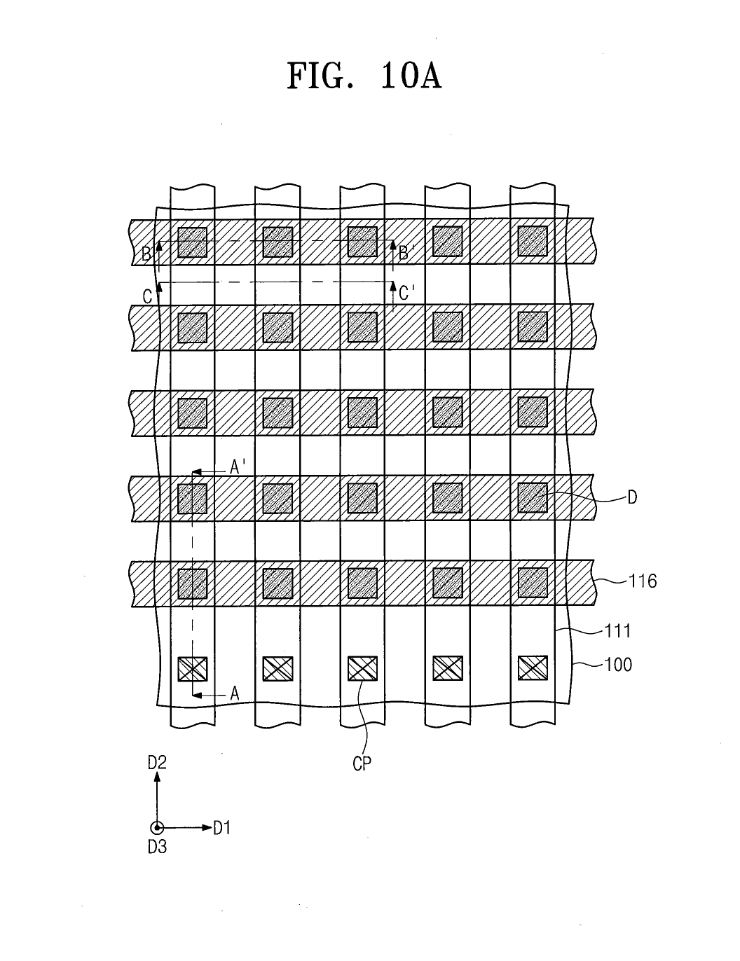

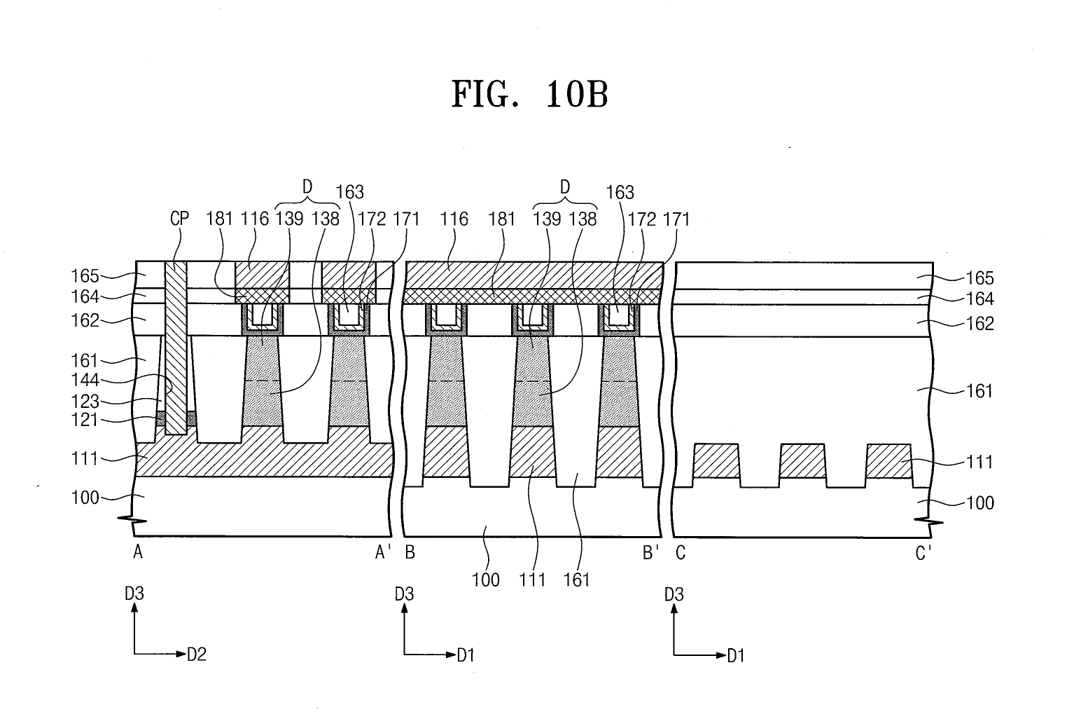

Referring to FIG. 10A and FIG. 10B, a planarization process may be performed on the resulting structure with the second insulating layer 163 to form silicide patterns 171 and lower electrode patterns 172. The silicide patterns 171 and the lower electrode patterns 172 may be formed on the diodes D. The silicide pattern 171, the lower electrode pattern 172, and the second insulating layer 163 may constitute a lower electrode structure.

Variable resistance patterns 181 may be formed on the lower electrode patterns 172. The variable resistance patterns 181 may extend parallel to the first direction D1. The variable resistance patterns 181 may be a phase-changeable layer. For concise description, a semiconductor device, in which the variable resistance patterns 181 is a phase-changeable layer, is described, but example embodiments of the inventive concepts may not be limited thereto. That is, the inventive concepts can be applied to other types of memory devices, such as other types of variable resistance memory devices.

The phase-changeable layer may be a material, whose phase or crystalline structure can be changed. The phase-changeable layer may be formed of a compound containing at least one chalcogenide element (e.g., Te and/or Se) and at least one of, for example, Ge, Sb, Bi, Pb, Sn, Ag, As, S, Si, P, O, and/or C. The variable resistance patterns 181 may be formed in a second interlayer insulating layer 164 exposing the lower electrode pattern 172.

Second conductive lines 116 may be formed on the variable resistance patterns 181. The second conductive lines 116 may be formed of transition metals, conductive transition metal nitrides and/or conductive ternary nitrides. The second conductive lines 116 may extend along the variable resistance patterns 181. The second conductive lines 116 may be formed to cross the first conductive lines 111 and extend in the first direction D1. For example, the second conductive lines 116 may serve as bit lines. The second conductive lines 116 may be provided in a third interlayer insulating layer 165 and may be electrically connected to the diodes D. An upper electrode (not shown) may be provided between the second conductive lines 116 and the variable resistance patterns 181. The second and third interlayer insulating layers 164 and 165 may include a silicon oxide layer and/or a silicon oxynitride layer.

Contact plugs CP may be formed to penetrate the patterned first gap-filling layer 123, the etch stop layer 121, and the first to third interlayer insulating layers 162, 164, and 165. The contact plugs CP may be electrically connected to the first conductive lines 111. The contact plugs CP may be provided in contact holes 144, which are formed to penetrate the first to third interlayer insulating layers 162, 164, and 165, the patterned first gap-filling layer 123, and the etch stop layer 121. The contact plugs CP may include a conductive material (e.g., doped semiconductors, metals, and/or conductive metal nitrides).

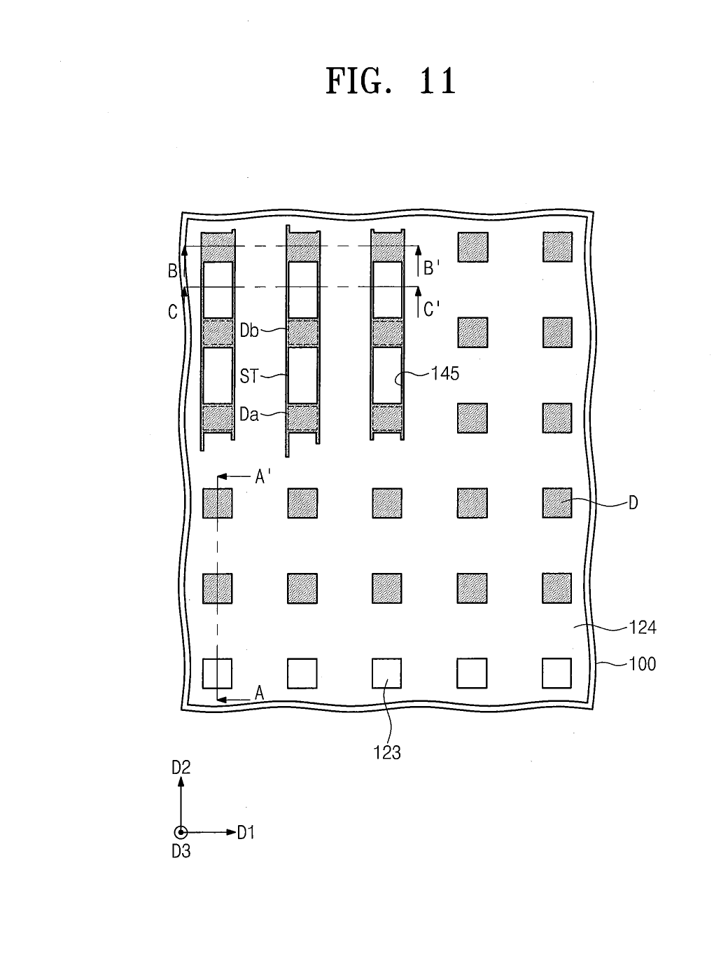

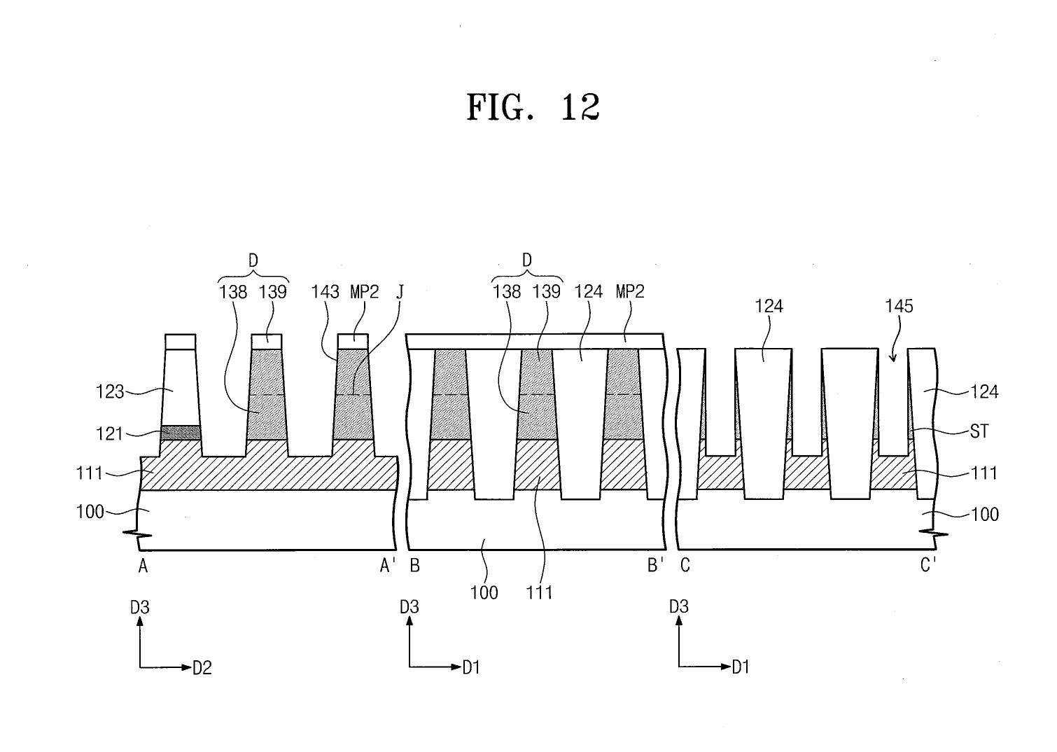

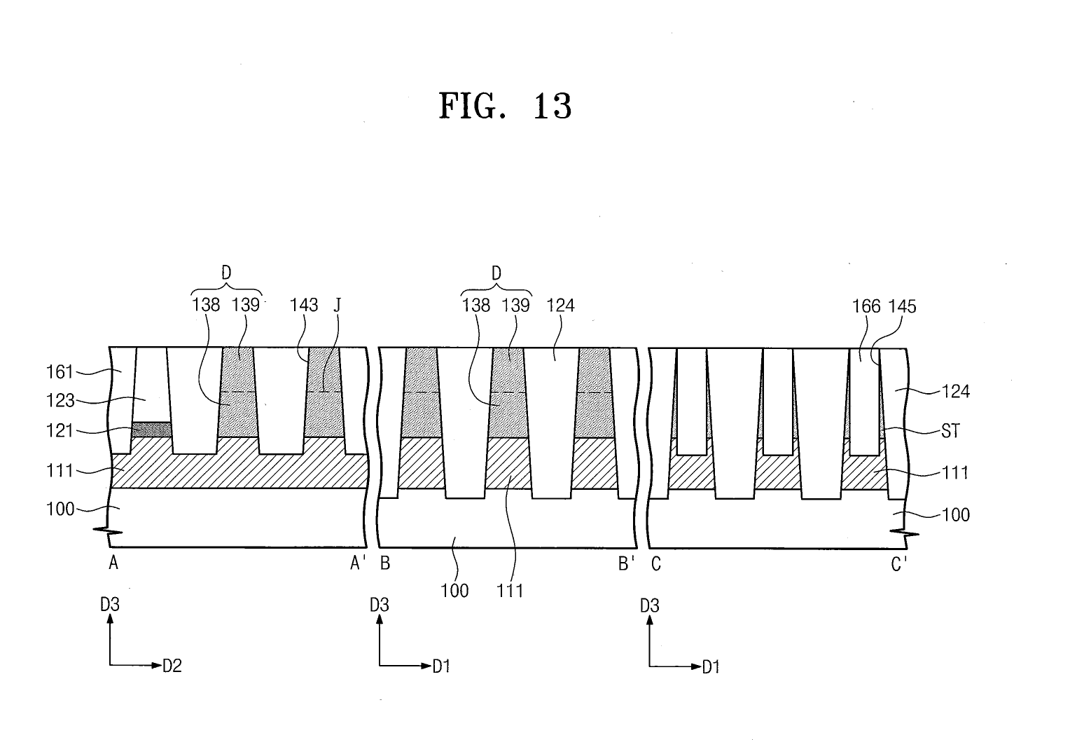

FIG. 11 is a schematic plan view illustrating a method of fabricating a variable resistance memory device according to a comparative example. FIGS. 12 and 13 are sectional views, each of which illustrates sections taken along lines A-A′, B-B′, and C-C′ of FIG. 11, and which are provided to illustrate a method of fabricating a variable resistance memory device according to the comparative example. According to a conventional method of fabricating a variable resistance memory device, a patterning process may be performed twice in X and Y directions to form diodes. For example, a patterning process in the X direction may be performed, and then, another patterning process in the Y direction may be performed on the resulting structure, in which a mold structure (e.g., the sacrificial patterns 124 described with reference to FIGS. 6A and 6B) remains, unlike example embodiments of the inventive concepts. In this case, the mold structure may lead to some problems.

For example, referring to FIGS. 11 and 12, diodes D may be formed on the resulting structure described with reference to FIGS. 6A and 6B. Here, unlike the previous embodiments described with reference to FIGS. 7A and 7B, the semiconductor patterns 135 may be patterned using the second mask patterns MP2 as an etch mask, in a state that the sacrificial patterns 124 is not removed. In other words, the semiconductor patterns 135 may be patterned in the first direction D1 to form the diodes D, which are two-dimensionally arranged on the substrate 100. In the comparative example, the sacrificial patterns 124 may be insulating patterns formed of a silicon oxide layer.

The patterning process in the first direction D1 may be performed by a dry etching process capable of selectively etching the semiconductor patterns 135. Accordingly, the semiconductor patterns 135 exposed by the second mask patterns MP2 may be selectively etched to form second openings 145 in the sacrificial patterns 124.

In the meantime, as described with reference to FIGS. 5A and 5B, the semiconductor patterns 135 may have a width decreasing in a direction away from the substrate 100. In particular, an increase in integration density of memory devices leads to a reduction in margin between patterns thereby increasing in height of the semiconductor patterns 135 (e.g., higher than 100 nm), and thus, a difference between top and bottom widths of the semiconductor patterns 135 may increase. For example, bottom widths of the semiconductor patterns 135 may be greater than widths of the second openings 145. Thus, the second regions RG2 (e.g., of FIGS. 6A and 6B) of the semiconductor patterns 135 may not be completely removed by the patterning process in the first direction D1 and may remain as stringers ST.

Referring back to FIG. 11, the diodes D may include a first diode Da and a second diode Db, which is spaced apart from the first diode Da in the second direction D2. The first diode Da and the second diode Db may be provided on each of the first conductive lines 111. Here, due to the stringers ST extending along the second direction D2, the first diode Da and the second diode Db may be electrically connected to each other. Accordingly, a short circuit may be formed between the first and second diodes Da and Db to cause malfunction of the selection devices and failure of the memory device.

In contrast, according to example embodiments of the inventive concepts, the patterning process in the first direction D1 may be performed on a structure, from which the sacrificial patterns 124 are partially or completely removed, as described with reference to FIGS. 7A, 7B, 8A, and 8B. Accordingly, it is possible to reduce or prevent the stringers ST from remaining, or to open circuit stringers that are present.

Referring to FIG. 13, a third insulating layer 166 may be formed to fill empty spaces, which are formed in the semiconductor patterns 135.

FIG. 10A also provides a schematic plan view illustrating a variable resistance memory device according to example embodiments of the inventive concepts. FIG. 10B is a sectional view illustrating sections taken along lines A-A′, B-B′, and C-C′ of FIG. 10A.

Referring back to FIGS. 10A and 10B, a substrate 100 may be provided. The substrate 100 may be a semiconductor substrate (e.g., of silicon, silicon germanium (SiGe), germanium (Ge), and/or gallium arsenic (GaAs)) and/or a semiconductor-on-insulator wafer such as a silicon-on-insulator (SOI) wafer.

First conductive lines 111 may be disposed on the substrate 100. The first conductive lines 111 may extend in a second direction D2 parallel to a top surface of the substrate 100. The first conductive lines 111 may be spaced apart from each other in a first direction D1 crossing the second direction D2. As an example, the first conductive lines 111 may serve as word lines in the resistance memory device.

As an example, the first conductive lines 111 may be a metallic layer which is formed of at least one of transition metals, conductive transition metal nitrides, and/or conductive ternary nitrides. As another example, the first conductive lines 111 may be an impurity region which is doped to have a second conductivity type different from that (i.e., a first conductivity type) of the substrate 100.

Diodes D may be two-dimensionally disposed in an array on the first conductive lines 111 and may be electrically connected to the first conductive lines 111. The diodes D may form a plurality of columns arranged in the first direction D1 and a plurality of rows arranged in the second direction D2 and along the first conductive lines 111. Each of the diodes D may include a lower impurity pillar 138 and an upper impurity pillar 139. The upper impurity pillar 139 may have the first conductivity type, and the lower impurity pillar 138 may have the second conductivity type. As an example, the upper impurity pillar 139 may be a p-type impurity region, and the lower impurity pillar 138 may be an n-type impurity region. The upper and lower impurity pillars 139 and 138 may constitute a p-n junction J or the diode D. The diodes D may be provided on word lines and serve as selection devices.

An etch stop layer 121 and a patterned first gap-filling layer 123 may be provided on end portions of the first conductive lines 111.

A first insulating layer 161 may be provided on, and in some embodiments to cover, the diodes D and the first conductive lines 111. The first insulating layer 161 may have a top surface coplanar with those of the diodes D. The first insulating layer 161 may include a silicon nitride layer, a silicon oxide layer and/or a silicon oxynitride layer.

First to third interlayer insulating layers 162, 164, and 165 may be sequentially stacked on the first insulating layer 161. The first to third interlayer insulating layers 162, 164, and 165 may include a silicon oxide layer and/or a silicon oxynitride layer.

A silicide pattern 171, a lower electrode pattern 172, and a second insulating layer 163 may be provided on each of the diodes D. The silicide pattern 171 may contribute to reduce a contact resistance between the diode D and the lower electrode pattern 172. The silicide pattern 171, the lower electrode pattern 172 and the second insulating layer 163 may constitute a lower electrode structure. The lower electrode structure may be provided in the first interlayer insulating layer 162 and have a top surface coplanar with that of the first interlayer insulating layer 162.

Variable resistance patterns 181 may be disposed on the lower electrode patterns 172, respectively. The variable resistance patterns 181 may extend in the first direction D1. The variable resistance patterns 181 may be a phase-changeable layer, whose phase or crystalline structure can be changed. The phase-changeable layer may be formed of a compound containing at least one chalcogenide element (e.g., Te and/or Se) and at least one of, for example, Ge, Sb, Bi, Pb, Sn, Ag, As, S, Si, P, O, and/or C. The variable resistance patterns 181 may be disposed in the second interlayer insulating layer 164.

Second conductive lines 116 may be provided on the variable resistance patterns 181. The second conductive lines 116 may include a transition metal, conductive transition metal nitride and/or conductive ternary nitride. The second conductive lines 116 may extend in the first direction D1 and cross the first conductive lines 111. As an example, the second conductive lines 116 may serve as bit lines. The second conductive lines 116 may be provided in the third interlayer insulating layer 165 and may be electrically connected to the diodes D. Upper electrodes (not shown) may be provided between the second conductive lines 116 and the variable resistance patterns 181.

Contact plugs CP may be electrically connected to the first conductive lines 111 through the patterned first gap-filling layer 123, the etch stop layer, and the first to third interlayer insulating layers 162, 164, and 165. The contact plugs CP may include a conductive material (e.g., doped semiconductors, metals and/or conductive metal nitrides).

In the variable resistance memory device according to the present embodiments, it is possible to completely separate the diodes D from each other (i.e., to reduce or prevent a short circuit between the diodes D). In the conventional case that the diodes D are formed through patterning processes to be performed in X and Y directions, stringers ST connecting the diodes D may be formed. However, according to the present embodiments, it is possible to prevent the stringers ST from being formed in the variable resistance memory device and/or to open circuit stringers that are formed, and thereby improve reliability of the variable resistance memory device.

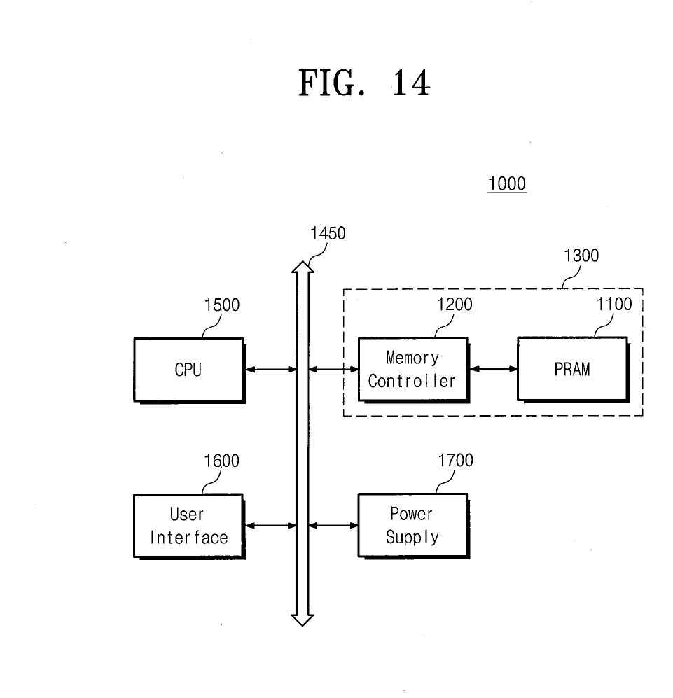

FIG. 14 is a block diagram illustrating an example of an electronic device including a variable resistance memory device according to example embodiments of the inventive concepts.

The electronic device 1000 according to example embodiments of the inventive concepts may be used in an application chipset, a camera image sensor, a camera image signal processor (ISP), a personal digital assistant (PDA), a laptop computer, a portable computer, a web tablet, a wireless phone, a mobile phone, a digital music player and/or a wire or wireless electronic device and/or a complex electronic device including at least two of the above listed devices.

Referring to FIG. 14, the electronic device 1000 may include a semiconductor memory device 1300, a central processing unit (CPU) 1500, a user interface 1600, and a power supply device 1700, which are connected to a system bus 1450. The semiconductor memory device 1300 may include a memory device 1100, which may be one of the afore-described variable resistance memory devices, and a memory controller 1200. A memory device according to embodiments of the inventive concepts may also be used in the CPU 1500, user interface 1600, memory controller 1200 and/or power supply 1700.

Data processed by the CPU 1500 and/or input from the user interface 1600 may be stored in the memory device 1100, and the memory controller 1200 may be configured to control such data exchange among the CPU 1500, the user interface 1600, and the memory device 1100. The memory device 1100 may constitute a solid state drive (SSD), and in this case, an operating speed of the electronic device 1000 may be fast.

According to example embodiments of the inventive concepts, a method of fabricating a variable resistance memory device may include performing a patterning process in an X direction and forming empty spaces between patterns. Thereafter, another patterning process in a Y direction may be performed, and thus, it is possible to prevent stringers from being formed between selection devices. Accordingly, it is possible to prevent short circuits from being formed between the selection devices and improved reliability of the device.

While example embodiments of the inventive concepts have been particularly shown and described, it will be understood by one of ordinary skill in the art that variations in form and detail may be made therein without departing from the spirit and scope of the attached claims.

1. A method of fabricating a semiconductor device, comprising:
forming a semiconductor layer on a substrate;
patterning the semiconductor layer in a first direction parallel to a top surface of the substrate to form semiconductor patterns extending parallel to the first direction;
forming sacrificial patterns in gap regions between the semiconductor patterns;
forming mask patterns on the semiconductor patterns and the sacrificial patterns extending parallel to a second direction crossing the first direction;
removing the sacrificial patterns; and
patterning the semiconductor patterns using the mask patterns as an etch mask to form an array of selection devices for a variable resistance memory device on the substrate.

2. The method of claim 1, wherein the forming sacrificial patterns comprises:
forming a sacrificial layer on the semiconductor patterns; and
planarizing the sacrificial layer to form the sacrificial patterns,
wherein the removing the sacrificial patterns is performed so that the semiconductor patterns and the mask patterns remain and the sacrificial patterns are removed.

3. The method of claim 1, wherein the sacrificial patterns comprise a spin on hardmask (SOH) layer, a silicon oxide layer or a silicon nitride layer, and
the sacrificial patterns are removed by an ashing process or an etching process, in which hydrogen fluoride or phosphoric acid is used.

4. The method of claim 1, wherein the removing the sacrificial patterns forms empty spaces below the mask patterns.

5. The method of claim 4, wherein the empty spaces are spaced apart from each other by the semiconductor patterns interposed therebetween and extend parallel to the first direction, and
the mask patterns span the empty spaces.

6. The method of claim 1, wherein the removing the sacrificial patterns is performed to expose top and side surfaces of the semiconductor patterns between the mask patterns.

7. The method of claim 1, wherein, when viewed in a plan view, each of the semiconductor patterns comprises:
first regions overlapped with the mask patterns; and
second regions exposed by the mask patterns,
wherein the patterning the semiconductor patterns comprises removing the second regions so that the first regions remain to form the array of selection devices.

8. The method of claim 7, wherein the removing the second regions completely separates the first regions from each other in the first direction.

9. The method of claim 1, wherein the semiconductor patterns have a width that decreases in a direction away from the substrate.

10. The method of claim 1, wherein the semiconductor patterns are separated from each other in the second direction.

11. The method of claim 1, wherein the forming a semiconductor layer on the substrate is preceded by forming a conduction region on the substrate, and
wherein the patterning the semiconductor layer in the first direction also patterns the conduction region into a plurality of conductive lines.

12. A method of fabricating a semiconductor device, comprising forming a semiconductor layer on a substrate;
patterning the semiconductor layer in a first direction parallel to a top surface of the substrate to form semiconductor patterns spaced apart from each other in a second direction crossing the first direction;
forming empty spaces between the semiconductor patterns; and then
patterning the semiconductor patterns in the second direction to form an array of selection devices for a variable resistance memory device on the substrate.

13. The method of claim 12, wherein the semiconductor patterns have sidewalls that have a positive slope.

14. The method of claim 12, wherein the patterning the semiconductor patterns in the second direction comprises:
forming mask patterns overlying the semiconductor patterns and the empty spaces in the second direction; and
etching top and side surfaces of the semiconductor patterns that are exposed by the mask patterns to form the selection devices between the etched portions of the semiconductor patterns, and
wherein the selection devices are separated from each other in the first direction.

15. The method of claim 4, further comprising:
forming a sacrificial layer in gap regions between the semiconductor patterns;
wherein the forming mask patterns comprises;
forming the mask patterns to cross the semiconductor patterns and the sacrificial layer and extend in the second direction; and
removing the sacrificial layer below the mask patterns to form the empty spaces so that the mask patterns overlie the semiconductor patterns and the empty spaces in the second direction, and
wherein the patterning the semiconductor patterns is performed to form first portions of the semiconductor patterns below the mask patterns and remove second portions of the semiconductor patterns exposed by the mask patterns.

16. A method of fabricating a semiconductor device,
comprising:
forming on a substrate, a plurality of semiconductor lines and insulator lines that extend along the substrate in a first direction;
forming on the semiconductor lines and insulator lines, a plurality of mask lines that extend along the substrate in a second direction that crosses the first direction;
removing at least portions of the insulator lines that lie beneath the plurality of mask lines; and then
patterning the plurality of semiconductor lines in the second direction using the plurality of mask lines.

17. The method of claim 16 wherein the removing comprises removing sufficient portions of the insulator lines beneath the plurality of mask lines to form an empty space beneath a respective mask line that extends across the respective mask line in the first direction.

18. The method of claim 16 wherein the removing comprises completely removing the portions of the insulator lines that lie beneath the plurality of mask lines so that the plurality of mask lines span across the substrate between adjacent ones of the semiconductor lines.

19. The method of claim 16 wherein the removing comprises completely removing the insulator lines.

20. The method of claim 16 wherein a respective semiconductor line comprises a p-n junction therein, and
wherein the patterning forms an array of spaced apart p-n junctions on the substrate that extends along the first and second directions.
